(19) United States
(12) Patent Application Publication
(10) Pub. No.: US 2007/0202645 A1
(43) Pub. Date: Aug. 30, 2007

(54) METHOD FOR FORMING A DEPOSITED OXIDE LAYER

(76) Inventors: Tien Ying Luo, Austin, TX (US); Lakshmanna Vishnubhotla, Austin, TX (US); Tushar P. Merchant, Austin, TX (US); Rajesh A. Rao, Austin, TX (US); Ramachandran Muralidhar, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/680,121

(22) Filed: Feb. 28, 2007

Related U.S. Application Data
(63) Continuation-in-part of application No. 11/364,128, filed on Feb. 28, 2006.

(51) Int. Cl. H01L 21/8242

(52) U.S. Cl. 438/255

(57) ABSTRACT

An oxide layer formed by deposition is subject to a treatment process to repair bond defects of the oxide layer. In one embodiment, the layer is treated with nitric oxide. In one embodiment, a nitric oxide gas is flowed over the dielectric layer at an elevated temperature. In still another embodiment, the oxide layer is treated with fluorine. A layer is deposited over the oxide layer and a species containing fluorine is ion implanted into the layer. The wafer is heated where the species is driven to the oxide layer.

### RELATED APPLICATIONS

This application is a continuation-in-part application of U.S. application Ser. No. 11/364,128 filed Feb. 28, 2006, and having a common assignee, all of which is incorporated by reference in its entirety.

### BACKGROUND OF THE INVENTION

1. Field of the Invention

This invention relates in general to a method for forming an oxide layer and more specifically to a method for forming a deposited oxide layer.

2. Description of the Related Art

Many logic and non volatile memory (NVM) devices use deposited oxides in the gate stack. Traditionally, deposited oxide layers are formed using processes, such as chemical vapor deposition. Deposited oxide layers suffer from several problems. In particular, such deposited oxide layers have many structural defects, including for example, Si dangling bonds, weak Si—Si bonds, and strained Si—O bonds. These structural defects can cause problems in the operation of devices having these deposited oxide layers because of undesirable phenomena, such as charge trapping in the oxide and trap-assisted tunneling of charges through the oxide. In addition, such deposited oxides may also include a significant hydrogen content in the layer, either in the form of Si—H or Si—OH bonds, which may also be a source of charge traps. By way of example, these phenomena can cause a shift in the threshold voltage of nanocluster memory devices. Further, in NVM devices, since the trapped charges in the deposited oxide layer are not electrically erased, they tend to accumulate with repeated program and erase cycles, resulting in an undesirable threshold voltage shift in these devices.

In some examples of deposited oxide formation, a high temperature oxide control film is formed by flowing a silicon precursor with N₂O as an oxidizing agent. N₂O (nitrous oxide) forms NO (nitric oxide) at high temperatures which oxidizes the Si precursor. However, an incomplete breakdown of N₂O into NO results in an incomplete oxidation of the Si bonds. As a result, a sub-stoichiometric oxide is deposited. Such an oxide may exhibit structural defects and charge trapping problems as described above. Additionally, it may be necessary to improve hot carrier immunity of deposited oxide without increasing substantially the total dielectric thickness.

Thus, there is a need for improved methods for forming a deposited oxide layer.

### BRIEF DESCRIPTION OF THE DRAWINGS

The present invention may be better understood, and its numerous objects, features, and advantages made apparent to those skilled in the art by referencing the accompanying drawings.

FIG. 1 is a partial side view of one embodiment of a semiconductor device during a processing stage, consistent with one embodiment of the invention;

FIG. 2 is a drawing illustrating exemplary micro-structural defects in a deposited oxide layer, consistent with one embodiment of the invention;

FIG. 3 is a partial side view of one embodiment of a semiconductor device during a processing stage, consistent with one embodiment of the invention;

FIG. 4 is a drawing illustrating exemplary removal of micro-structural defects in a deposited oxide layer, consistent with one embodiment of the invention;

FIG. 5 is a partial side view of one embodiment of a nanocluster device during a processing stage, consistent with one embodiment of the invention;

FIG. 6 is a partial side view of one embodiment of a nanocluster device during a processing stage, consistent with one embodiment of the invention;

FIG. 7 is a partial side view of one embodiment of a nanocluster device during a processing stage, consistent with one embodiment of the invention;

FIG. 8 is a partial side view of one embodiment of a nanocluster device during a processing stage, consistent with one embodiment of the invention; and

FIG. 9 is a partial side view of one embodiment of a nanocluster device during a processing stage, consistent with one embodiment of the invention.

FIG. 10 is a partial side view of one embodiment of a semiconductor device during a processing stage, consistent with one embodiment of the invention.

FIG. 11 is a partial side view of one embodiment of a semiconductor device during a processing stage, consistent with one embodiment of the invention.

FIG. 12 is a partial side view of one embodiment of a semiconductor device during a processing stage, consistent with one embodiment of the invention.

FIG. 13 is a partial side view of one embodiment of a semiconductor device during a processing stage, consistent with one embodiment of the invention.

FIG. 14 is a partial side view of one embodiment of a semiconductor device during a processing stage, consistent with one embodiment of the invention.

FIG. 15 is a partial side view of one embodiment of a semiconductor device during a processing stage, consistent with one embodiment of the invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

The following sets forth a detailed description of a mode for carrying out the invention. The description is intended to be illustrative of the invention and should not be taken to be limiting.

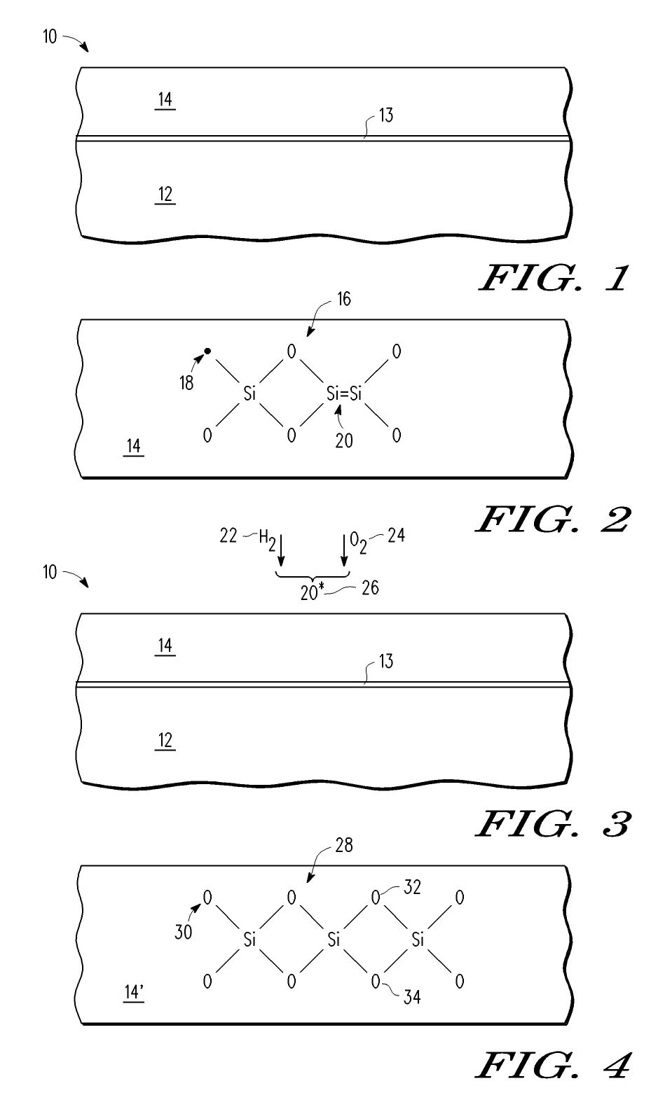

FIG. 1 is a partial side view of one embodiment a semiconductor device during a processing stage, consistent with one embodiment of the invention. Semiconductor device 10 may include a substrate 12. A barrier layer 13 may be formed over substrate 12. Barrier layer 13 may be a nitride layer or any other suitable barrier layer or layers. Next, a deposited oxide layer 14, such as a SiO₂ layer may be formed over substrate 12 using chemical vapor deposition or plasma-enhanced chemical vapor deposition, for example. As shown in FIG. 2, deposited oxide layer 14 may have several micro-structural defects 16. Such micro-structural defects may include bond defects, such as silicon dangling bond 18 and weak silicon-silicon bond 20.

Referring now to FIG. 3, deposited oxide layer 14 may be annealed in the presence of oxygen radicals. By way of example, using techniques, such as in-situ steam generation (ISSG), deposited oxide layer 14 may be annealed in the presence of oxygen radicals. Thus, as shown in FIG. 3, hydrogen (H₂) 22 and oxygen (O₂) 24 may be introduced into a chamber containing semiconductor device 10 at a temperature ranging between 800-1100 degrees Celsius. Hydrogen 22 and oxygen 24 may react over deposited oxide layer 14 to form oxygen radicals (2O*) 26. By way of example, 1% of hydrogen may be combined with 99% of oxygen to form oxygen radicals (2O*) 26. In general, by way of example, 0.5% to 33% hydrogen may be used as part of the hydrogen and oxygen mixture. Oxygen radicals 26 may repair at least some of the micro-structural defects shown in FIG. 2. In particular, as shown with reference to FIG. 4, oxygen radicals 26 may be incorporated into the SiO₂ network to form oxygen atoms that share covalent bonds 30, 32, and 34, for example, with silicon atoms that were previously associated with bond defects (18 and 20 in FIG. 2). Thus, this process of annealing deposited oxide layer 14 in the presence of oxygen radicals 26 may result in a stoichiometric structure 28 in deposited oxide layer 14′. In particular, a substantial number of bond defects, such as silicon dangling bonds and weak silicon-silicon bonds may be repaired by using this process. Other techniques, such as plasma O₂ or ultra-violet O₂ anneal may also be used to generate the oxygen radicals. By way of example, either prior to performing the ISSG anneal or after performing the ISSG anneal, semiconductor device 10 may be subjected to an inert anneal. The inert anneal process may densify deposited oxide layer 14/14′. The inert anneal process may further lead to hydrogen desorption from deposited oxide layer 14/14′. The inert anneal process may be performed by subjecting semiconductor device 10 to an inert gas, such as nitrogen, argon, or helium in a chamber at a temperature in a range of 800 to 1200 degrees Celsius.

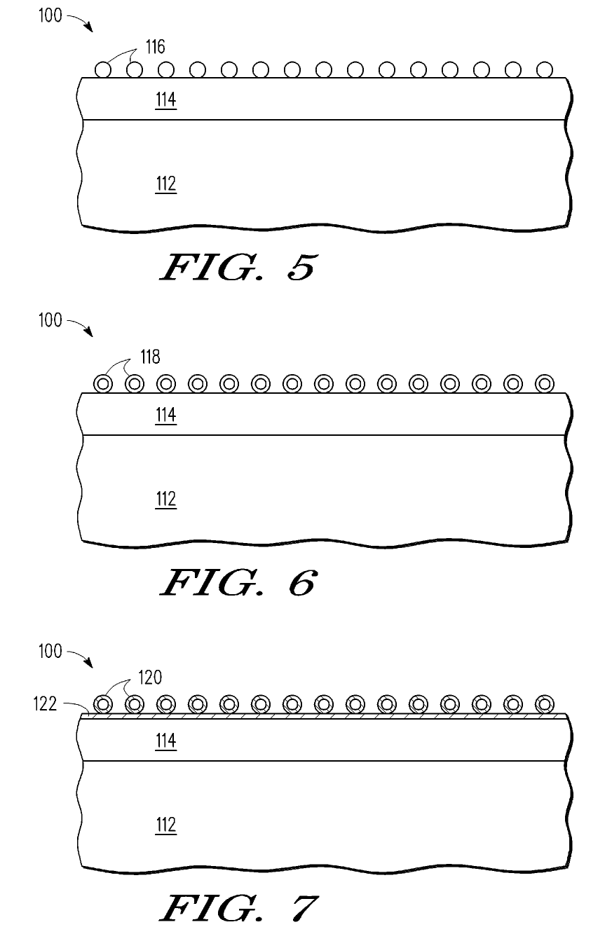

FIG. 5 shows an exemplary nanocluster device 100 during a processing stage. Nanocluster device 100 may include a substrate 112, a thermally grown oxide layer 114, and nanoclusters 116 formed over thermally grown oxide layer 114. Thermally grown oxide layer 114 may act as an insulating layer. Nanocluster device 100 may be used as part of a non-volatile memory, for example as part of the gate structure. Nanoclusters 116 may act as a charge storage layer. Although FIG. 5 shows nanoclusters 116 acting as a charge storage layer, other structures, such as a nitride layer may be used as the charge storage layer.

Next, as shown in FIG. 6, passivated nanoclusters 118 may be formed by thermal oxidation in a nitrogen containing atmosphere, such as nitric oxide, nitrous oxide, or ammonia. Additionally and/or alternatively, passivated nanoclusters 118 may be subjected to nitridation, as shown in FIG. 7. Nitridation may result in nitrided nanoclusters 120 and a nitrided layer 122 overlying thermally grown oxide layer 114. Nitridation could be performed using a plasma process.

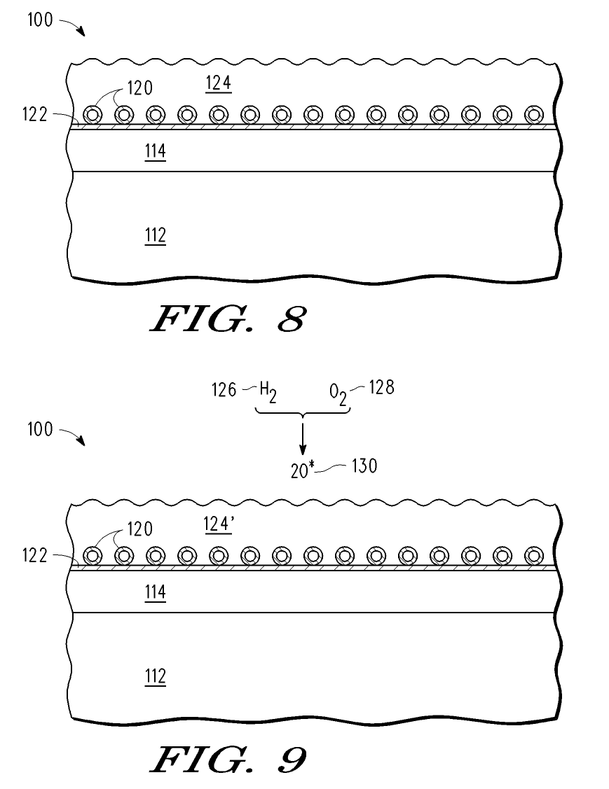

Next, as shown in FIG. 8, a deposited oxide layer 124 may be formed over nitride layer 122 and nitrided nanoclusters 120. Deposited oxide layer 124, such as a SiO₂ layer may be formed using chemical vapor deposition or plasma-enhanced chemical vapor deposition, for example. Although FIG. 8 shows nitrided nanoclusters 120, the nanoclusters need not be nitrided. Deposited oxide layer 124 functions as a control dielectric of nanocluster memory device 100.

Referring now to FIG. 9, deposited oxide layer 124 may be annealed in the presence of oxygen radicals. By way of example, using techniques, such as in-situ steam generation (ISSG), deposited oxide layer 124 may be annealed in the presence of oxygen radicals. By way of example, hydrogen (H₂) 126 and oxygen (O₂) 128 may be introduced into a chamber containing semiconductor device 100 at a temperature ranging between 800-1100 degrees Celsius. Hydrogen 126 and oxygen 128 may react over deposited oxide layer 124 to form oxygen radicals (2O*) 130. By way of example, 1% of hydrogen may be combined with 99% of oxygen to form oxygen radicals (2O*) 130. In general, by way of example, 0.5% to 33% hydrogen may be used as part of the hydrogen and oxygen mixture. Oxygen radicals 130 may repair at least some of the micro-structural defects, for example, as shown above with reference to FIG. 2. In particular, as shown above with reference to FIG. 4, oxygen radicals 130 may form co-valent silicon-oxygen bonds, for example. Thus, this process of annealing deposited oxide layer 124 in the presence of oxygen radicals 130 may result in a deposited oxide layer 124′ having a stoichiometric structure. In particular, a substantial number of bond defects, such as silicon dangling bonds and weak silicon-silicon bonds may be repaired by using this process. Other techniques, such as plasma O₂ or ultra-violet O₂ anneal may also be used to generate the oxygen radicals. By way of example, either prior to performing the ISSG anneal or after performing the ISSG anneal, semiconductor device 100 may be subjected to an inert anneal. The inert anneal process may density deposited oxide layer 124/124′. The inert anneal process may further lead to hydrogen desorption from deposited oxide layer 124/124′. The inert anneal process may be performed by subjecting semiconductor device 100 to an inert gas, such as nitrogen, argon, or helium in a chamber at a temperature in a range of 800 to 1200 degrees Celsius.

Repair of deposited oxide layer 124 may result in removal of a substantial number of bond defects from deposited oxide layer 124. This may result in reduction in charge trapping in the oxide and associated threshold voltage shifts during program/erase operation of the nanocluster device, such as a non-volatile memory device.

FIGS. 10-14 show various stages of the manufacture of a non volatile memory where the deposited control dielectric is subject to a treatment of nitric oxide for the reduction of structural defects in the control dielectric oxide.

FIG. 10 is a partial side view of wafer 1001. Wafer 1001 includes a substrate 1003 with a dielectric tunnel layer 1005 formed thereon. In one embodiment, dielectric tunnel layer 1005 is a thermally grown oxide layer. However, in other embodiments, layer 1005 maybe deposited. In the embodiment shown, substrate 1003 is a bulk silicon substrate but may be of other materials and/or other configurations (e.g. a semiconductor on insulator configuration) in other embodiments.

Nanoclusters 1007 are formed on layer 1005. In one embodiment, nanoclusters 1007 are silicon nanoclusters. However, in other embodiments, nanoclusters may be made of other materials (e.g. metal nanoclusters or other type of nanoclusters such as silicon germanium nanoclusters). Nanoclusters 1007 are a type of discontinuous storage material that is used for selectively storing charge in a non volatile memory device for storing information by the memory.

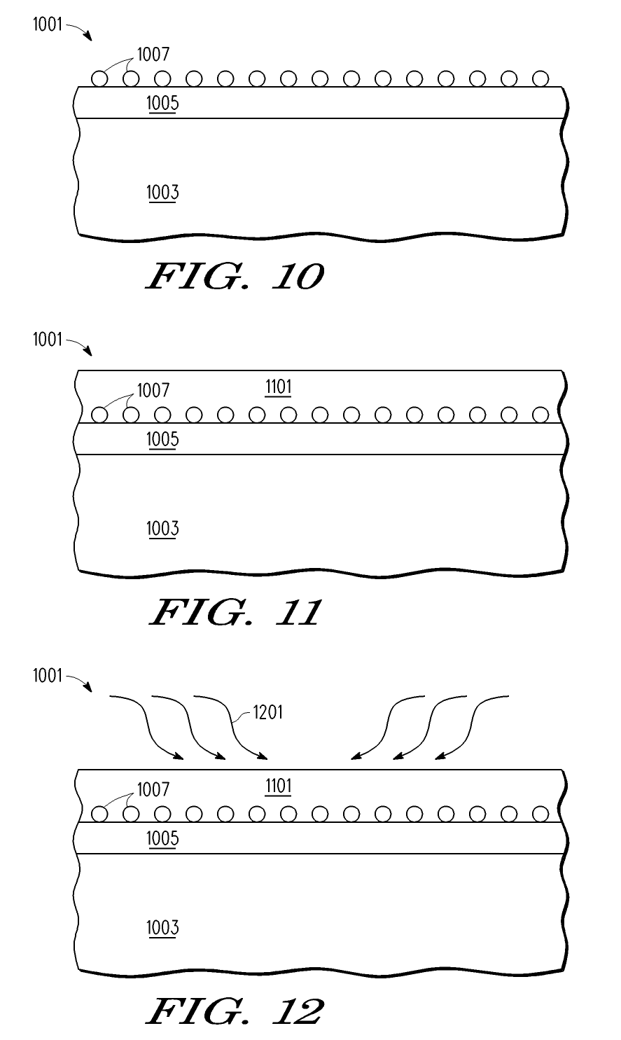

FIG. 11 is a partial side view of wafer 1001 after the deposition of a control oxide layer 1101 on nanocrystals 1007 and on exposed portions of layer 1005. Deposited oxide layer 1101, (e.g. an SiO₂ layer) may be formed e.g. using chemical vapor deposition or plasma-enhanced chemical vapor deposition. In one embodiment, layer 1101 is formed using silane and nitrous oxide as precursors at a temperature in a range of 600 to 1000 C. In one embodiment, nanoclusters 1107 may be nitrided prior to forming layer 1101.

As described with respect to layer 14 (of FIG. 2) above, layer 1101 includes micro-structural defects such as bond defects, e.g. silicon dangling bonds, weak silicon-silicon bonds, and strained silicon oxygen bonds. Layer 1101 may also include other types of bond defects such as silicon hydrogen bonds Si—H and Si—OH, which may also be a source of undesirable charge traps.

FIG. 12 is a side view of wafer 1001 during an application of a nitric oxide precursor for treating control dielectric layer 1101 with nitric oxide to repair bond defects such as e.g. dangling silicon, weak silicon-silicon bonds, strained silicon oxygen bonds and/or silicon hydrogen bonds.

In one embodiment, the nitric oxide precursor 1201 is NO gas supplied in a chamber in which the wafer is heated at a temperature within the range 700-1100 C. In one embodiment, the temperature may be around 875 C. In one embodiment, the nitric oxide precursor is flowed at a pressure in the range of 1-100 Torr. In one embodiment, the nitric oxide precursor may be flowed in the presence of an inert gas (e.g. N₂, Ar, He). During the treatment, bond defects such as silicon dangling, weak silicon-silicon bonds, strained silicon oxygen bonds, and/or silicon hydrogen bonds may be repaired. In one embodiment, the application of the nitric oxide precursor may result in the presence of nitrogen in layer 1101 at a percentage greater than 1 atomic percent. In other embodiments, the nitric oxide precursor may include nitrogen and oxygen radicals

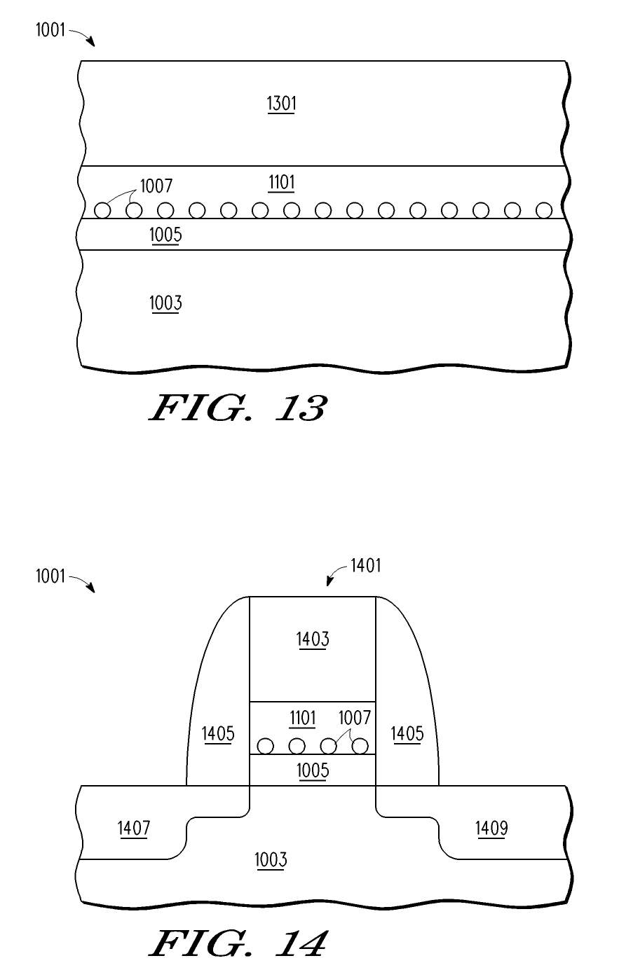

FIG. 13 shows a partial side view of wafer 1001 after the deposition of a layer of control gate material. In one embodiment control gate material layer 1301 may be polysilicon, a metal, or other control gate material.

FIG. 14 shows a partial side view of wafer 1001 after a non volatile memory device (transistor 1401) is formed. Transistor 1401 includes a charge storage structure having a portion of nanoclusters 1007 with layer 1101 located there over. In one embodiment, layer 1005, nanoclusters 1007, layer 1101, and layer 1301 are patterned to form a gate stack that includes gate 1403 formed from layer 1301. In the embodiment shown, after patterning, lightly doped source drain extensions are formed by implanting dopants (e.g. phosphorous, arsenic, boron) into substrate 1003. Dielectric sidewall spacers 1405 are then formed e.g. by conventional methods. Afterwards, heavily doped source/drain regions 1407 and 1409 are formed by implanting dopants into those regions and activating the dopants by annealing.

In other embodiment, charge storage devices may have other configurations and/or have other structures. For example, transistor 1401 is a planar transistor. However, a charge storage device may have a trench transistor configuration where the nanoclusters may be located in a trench or a FinFET configuration where the nanoclusters are located adjacent to the sidewalls of a channel structure. In other embodiments, the charge storage device may have a split gate configuration where the nanoclusters are located below the control gate and maybe in the gap between the control gate and select gate.

Subsequent processes may be preformed on wafer 1001 after the stage shown in FIG. 14. For example, silicide (not shown) may be formed on source/drain regions 1407 and 1409 and on gate 1403. Contacts (not shown) maybe be formed to electrically contact the silicide structures. Also interconnects and dielectrics (not shown) maybe formed over wafer 1001 followed by the formation of external conductive structures (e.g. bond pads) and passivation layers (none shown). Wafer 1001 may be subsequently singulated (e.g. with a wafer saw) into individual integrated circuits. Each integrated circuit may include memory devices with arrays of transistors similar to transistor 1401.

In one embodiment, charge maybe stored in the nanoclusters 1007 of transistor 1401 by performing a charge programming operation on transistor 1401. In one embodiment, a programming operation may include applying a programming pulse to gate 1403 and source/drain region 1409 while biasing region 1407 at a lower voltage (e.g. ground). Examples of programming operations include Fowler Nordheim and hot carrier injection programming operations.

Because layer 1101 was subjected to a treatment of nitric oxide, bond defects e.g. dangling silicon, weak silicon-silicon bonds, strained silicon oxygen bonds, and/or silicon hydrogen bonds may be repaired so as to reduce undesirable charge trapping in layer 1101 of transistor 1401. During the treatment, the nitrogen and oxygen of the nitric oxide passivate dangling bonds, replace the weak silicon-silicon bonds, replace strained silicon oxygen bonds, and replace silicon hydrogen bonds. Accordingly, when transistor 1401 is subject to a programming operation, the amount of undesired charge that accumulates during such cycles in layer 1101 is minimized. Accordingly, the number of life cycle programming operations of the non volatile memory device may be increased.

In other embodiments where layer 1005 is deposited, the nitric oxide treatment as shown in FIG. 12 may also reduce defects in that layer.

In other embodiments, other types of dielectric layers may be subject to a nitric oxide treatment for defect repair. For example, a dielectric layer similar to layer 14 may be subject to the nitric oxide treatment in lieu of the ISSG process as shown in FIG. 3 or in addition to the ISSG process.

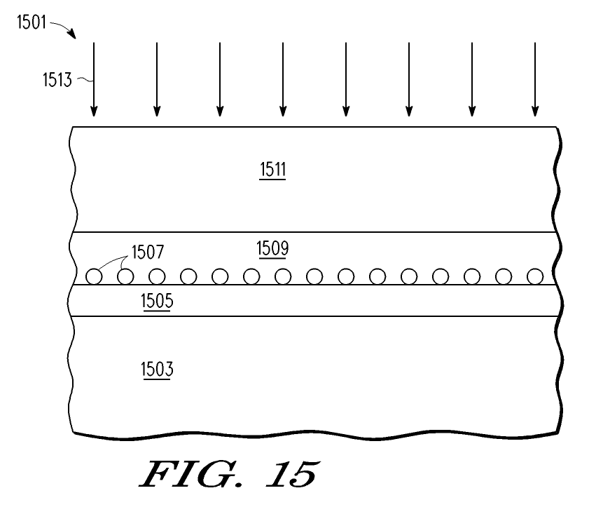

FIG. 15 is a partial side view of a wafer 1501 in which a polysilicon layer 1511 is being implanted with fluorine 1513 (BF₂ or F₂) for the treatment of deposited oxide layer 1509 with fluorine. Such a fluorine treatment may be utilized to correct silicon bond defects (as described above) of layer 1509.

In one embodiment, substrate 1503, dielectric layer 1505, nanoclusters 1507, and dielectric layer 1509 are similar to substrate 1003, layer 1005, nanoclusters 1007, and dielectric layer 1101, respectively. A layer 1511 of polysilicon (e.g. 1000-1500 angstrom) is deposited on layer 1509.

A species containing fluorine (BF₂, F₂, or F) is ion implanted into layer 1511. In one embodiment, F₂ is ion implanted at a dose in the range of 1e¹⁴ to 1e¹⁶ per cm² and at an energy in the range 5-20 KeV. Species containing fluorine may be implanted at other energies and at other doses in other embodiments. In some embodiments, the species containing fluorine may include one or more of BF₂, F₂, or F.

After the implantation of the species containing fluorine, the wafer is heated (e.g. at 950 C for one hour) to drive the species from layer 1511 to layer 1509 and to form Si—F bonds in the SiO₂ lattice of layer 1509. These Si—F bonds replace weak Si bonds, strained Si—O bonds, and Si—H and Si—OH bonds in the lattice. The fluorine also forms Si—F bonds with dangling silicon of layer 1509.

Utilizing layer 1511 as an implant layer allows layer 1509 to be treated with fluorine without damaging layer 1509 due to the ion implantation. In some embodiments, layer 1511 may be removed after treatment wherein a control gate layer would be formed on layer 1509. In other embodiments, layer 1511 would be used as a control gate layer.

In subsequent embodiments, layer 1509 would be patterned when forming gate stacks for transistors with charge storage structures (e.g. similar to transistor 1401).

In other embodiments, other types of dielectric layers maybe be treated with fluorine in a manner similar to that described above to repair defects in the dielectric layer. For example, a dielectric layer similar to layer 14 may be treated with fluorine to repair defects in the layer.

As stated above, this disclosure sets forth various embodiments for repairing structure defects such as e.g. dangling silicon, weak silicon-silicon bonds, strained silicon oxygen bonds or silicon hydrogen bonds in a deposited oxide layer. These defects are repaired by forming Si—N or Si—F bonds that are not easily broken by hot electrons during programming operations. Accordingly, in some embodiments, such processes may be used to provide a deposited oxide layer of a quality that approaches that of a thermally grown oxide layer.

In other embodiments, layer 1509 may be treated with fluorine by flowing a precursor including fluorine (e.g. a carbon tetra fluoride precursor) in an Argon ambient over layer 1509.

In other embodiments, combinations of post deposition treatments may be used to correct structural defects of a deposited oxide layer. For example a deposited oxide layer may be subject to an ISSG process, nitric oxide treatment, and a fluorine treatment to repair defects. In other embodiments, a deposited oxide layer may be subject to two of the processes for defect repair.

In one embodiment, a method for forming a semiconductor device includes providing a substrate, depositing an oxide layer overlying the substrate, and applying a substance comprising nitric oxide or fluorine to the oxide layer after depositing the oxide layer.

In another embodiment, a method for forming a semiconductor device includes providing a substrate, forming a first oxide layer overlying the substrate, and forming a charge storage layer overlying the first oxide layer. The charge storage layer includes nanoclusters. The method includes depositing a second oxide layer overlying the charge storage layer and applying a substance comprising nitric oxide to the second oxide layer after the depositing the second oxide layer.

In another embodiment, a method for forming a semiconductor device includes providing a substrate, forming a first oxide layer overlying the substrate, and forming a charge storage layer overlying the first oxide layer. The charge storage layer includes nanoclusters. The method also includes depositing a second oxide layer overlying the charge storage layer and applying a substance including fluorine to the second oxide layer.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

What is claimed is:

1. A method for forming a semiconductor device, comprising:
providing a substrate;
depositing an oxide layer overlying the substrate; and
applying a substance comprising nitric oxide or fluorine to the oxide layer after depositing the oxide layer.

2. The method of claim 1, wherein applying the substance further comprises applying the substance while the semiconductor device is at a temperature in a range of seven hundred degrees Celsius to one thousand one hundred degrees Celsius.

3. The method of claim 1 further comprising forming a charge storage layer prior to depositing the oxide layer.

4. The method of claim 3, wherein the charge storage layer comprises nanoclusters.

5. The method of claim 3 further comprising:
forming a conductive layer overlying the oxide layer; and
patterning the conductive layer to form a control gate for a non-volatile memory transistor.

6. The method of claim 1 further comprising performing an oxidation process using oxygen radicals on the semiconductor device after depositing the oxide layer.

7. The method of claim 1, wherein applying a substance comprising nitric oxide or fluorine further comprises applying a substance to remove bond defects in the oxide layer that form undesirable electron traps in the oxide layer.

8. The method of claim 1, wherein applying a substance further comprises:
depositing a polysilicon layer overlying the oxide layer;
ion implanting a chemical species comprising fluorine into the polysilicon layer; and
annealing the semiconductor device to drive fluorine into the oxide layer.

9. The method of claim 1, wherein the applying a substance includes applying a substance including nitric oxide.

10. The method of claim 9 wherein the applying the substance further comprising:
flowing a nitric oxide precursor over the oxide layer.

11. The method of claim 10 wherein the flowing a nitric oxide precursor over the oxide layer further comprising:
flowing a nitric oxide gas over the oxide layer.

12. The method of claim 1 wherein the oxide layer includes silicon oxide.

13. The method of claim 1, wherein applying a substance includes applying a substance including fluorine.

14. A method for forming a semiconductor device, comprising:
providing a substrate;
forming a first oxide layer overlying the substrate;
forming a charge storage layer overlying the first oxide layer, the charge storage layer comprising nanoclusters;
depositing a second oxide layer overlying the charge storage layer; and
applying a substance comprising nitric oxide to the second oxide layer after the depositing the second oxide layer.

15. The method of claim 14 further comprising:
forming a conductive layer overlying the second oxide layer; and
patterning the conductive layer to form a control gate for a non-volatile memory transistor.

16. The method of claim 14 wherein the applying a substance comprising nitric oxide further includes flowing a nitric oxide precursor over the second oxide layer.

17. The method of claim 16 wherein the flowing a nitric oxide precursor over the second oxide layer further includes flowing a nitric oxide gas over the second oxide layer.

18. The method of claim 14 wherein the second oxide layer includes silicon oxide.

19. The method of claim 14 wherein the applying a substance comprising nitric oxide to the second oxide layer is performed while heating the semiconductor device at a temperature in a range of seven hundred degrees Celsius to one thousand one hundred degrees Celsius.

20. A method for forming a semiconductor device, comprising:
providing a substrate;
forming a first oxide layer overlying the substrate;
forming a charge storage layer overlying the first oxide layer, the charge storage layer comprising nanoclusters;
depositing a second oxide layer overlying the charge storage layer;
applying a substance including fluorine to the second oxide layer.

21. The method of claim 20 wherein the applying a substance including fluorine to the second oxide layer further includes:
depositing a layer overlying the second oxide layer;
ion implanting a chemical species comprising fluorine into the layer; and
annealing the semiconductor device to drive fluorine into the second oxide layer.

22. The method of claim 21, further comprising removing the layer after annealing the semiconductor device.

23. The method of claim 21 wherein the layer includes polysilicon, the method further comprising:
patterning the layer to form a control gate for a non-volatile memory transistor.

24. The method of claim 20 wherein the second oxide layer includes silicon oxide.

25. The method of claim 20 wherein the applying a substance including fluorine to the second oxide layer includes flowing a precursor containing fluorine over the second oxide layer.
